(19) United States
(12) Patent Application Publication
(10) Pub. No.: US 2003/0132700 A1
(43) Pub. Date: Jul. 17, 2003

(54) Method and apparatus for reducing colour shift in a display screen when viewed off-centre

(76) Inventor: Antony van de Ven, Hong Kong (HK)

Correspondence Address: JACOBSON HOLMAN, PROFESSIONAL LIMITED LIABILITY COMPANY, 400 SEVENTH STREET, N.W., WASHINGTON, DC, 20004, US

(21) Appl. No.: 10/046,552

(22) Filed: Jan. 16, 2002

(51) Int. Cl. H01L 23/06; H05B 33/22

(52) U.S. Cl. 313/500

(57) ABSTRACT

This invention provides a method and apparatus for reducing colour shift in a display screen when a viewer moves to view the screen from an off-centre position. When pixels of LEDs are provided in an asymmetric arrangement, there will not be an equal obscuring effect from one LED on an adjacent LED as the viewer moves off-centre. This is due to an uneven spacing between the LEDs in an asymmetric arrangement. The invention provides protrusions or other obscuring means that may be inserted into the array of LEDs between those LEDs suffering the least obscuring in view of centre so as to equate with those LEDs suffering the most obscuring effect. This brings the light-emitting elements to an even obscuring effect as a viewer moves off-centre to avoid any colour shift.

### FIELD OF THE INVENTION

This invention relates to a method and apparatus for reducing colour shift in a display screen when viewed off-centre. In particular, the method and apparatus are directed to display screens utilizing pixels having an asymmetrical arrangement of light-emitting elements such as LEDs that protrude from a front face of the display screen.

### BACKGROUND TO THE INVENTION

In display screens that utilize discrete light-emitting elements for different colours, the light-emitting elements are generally arranged into pixels having a minimum of three different light-emitting elements that can complement each other to provide the full range of colours. In a typical display screen using light-emitting diodes or similar, this might comprise red, blue and green LEDs.

The LEDs in such a display screen are generally arranged in a matrix of rows and columns of LEDs. They are arranged to provide a pixelated display screen that provides a particular appearance to a typical viewer standing directly in front of the screen. This is a central viewer position in a direction substantially orthogonal to the front face of the display screen.

In practice, large display screens of this type may be used in outdoors settings such as sports stadiums and the like. They are regularly placed at one-end of a playing field. Aside from those substantially in front of the screen, a significant number of viewers may be further towards the sides of the screen and viewing the screen from an off-centre position.

A first prior art portion of an LED display screen is shown in FIGS. 1a and 1b. A typical pixel may utilize, in this particular example, four LEDs arranged in a square format such as a red, two green and a blue LED.

It should be noted that the use of more than one of the three typical colours, such as the use of two green LEDs in this example, may be useful. A video image typically requires an average colour intensity of approximately 30% red, 60% green and 10% blue. To compensate for the dominant green usage, an additional green LED may share the workload of the green signal for the overall image from the pixel. However, many other variations are possible and consideration is given to the efficiencies of the various materials for making such LEDs. All of which are available at varying costs.

For example, a single red LED may be capable of providing the 30% red component if made from a particularly expensive material. However, it may be more economic to share the workload of the red LED between two separate cheaper red LEDs. Further, although the green percentage is relatively high, it is possible that materials are used that provide particularly high intensity green LEDs at a low cost. A single green, two red LEDs and a blue LED might provide a cheaper overall pixel. These cost efficiencies may change as different materials are developed for the various LEDs. These are not restricted to arrangements of four LEDs but also might provide cost efficiencies if only three LEDs such as a red, blue and green are utilized or more such as five, six or seven LEDs in various ratios.

In the prior art arrangement as shown in FIG. 1b, it can be appreciated that when viewed side-on, the LEDs protrude from the front face of the screen through the provision of the lens on the LED. As higher quality screens are provided by increasing the density of the LEDs, the spacing between the LEDs reduces. If viewed side-on as shown in FIG. 1b, the closest red LED entirely obscures all the other LEDs in the same row.

In practice, a viewer directly side-on to a screen will not receive any image other than the end colour of LEDs, nor are screens intended to provide such a viewer with an image. However, at positions between that substantially in plane with the front face and a position orthogonal to the front face, a single LED will obscure the adjacent distal LED by varying amounts. Although this leads to an overall drop in the intensity of the image provided to a viewer as they progress from the central position more to one side, such a drop in intensity may be acceptable if it is not accompanied by distortion of the image itself.

Referring to FIG. 1a, it can be seen that the rows of LEDs are provided such that the LEDs may have substantially equal spacing between each other. For example, the spacing between a red LED and the adjacent green LED is equal to the spacing to the next red LED and so on. When a viewer moves further to the side, the degree by which one LED obscures the next is substantially constant along the entire row of LEDs. Hence the perceived image by a viewer of that row of red and green LEDs does not significantly change in terms of the ratio of red and green light received. Hence, there is no perceived colour shift in such an arrangement. Similarly, the lower row of green and blue LEDs will cause no significant distortion in terms of colour shift of the image as each blocks the next by an equal amount due to equal spacing between each successive LED.

A similar consideration needs to be provided with respect to a viewer that is at various different locations in a vertical plane coinciding with the screen. For example, a viewer looking directly at the display screen at the same height as the display screen sees each of the LEDs front-on and there is no obscuring of the LEDs. However, in most uses a viewer is positioned below the display screen at varying angles. To reduce sunload on particularly outdoors screens, louvers or shaders are generally provided as shown in FIGS. 1a and 1b. These louvers or shaders provide a degree of obscurity to the row of LEDs directly adjacent but distal from the viewers position below the screen. It will be appreciated that in the arrangement shown in FIG. 1a, a viewer looking up at the screen at a more acute angle may receive a significant degree of obscuring of the green and blue row of LEDs just above each of the shaders. There may be significantly less obscuring of the upper red and green row of LEDs. To such a viewer, the reduction in the blue and a portion of the green content may cause a colour-shift in the image more towards the red range and disturb the image as intended.

To alleviate such a problem a further prior art arrangement is shown in FIG. 2. Although the arrangement of LEDs in the form of a pixel is still in the same format as FIG. 1a, it can be noticed that shaders are provided intermediate of every row such that a viewer positioned at various points on a vertical plane in front of the display screen will receive an image in which every LED is obscured by the shader to an equal degree. This provides a substantially equal degree of obscuring of the LEDs regardless of the portion of the viewer on planes passing through two orthogonal axis to the front face of the display screen.

As mentioned previously, cost efficiencies and other considerations can cause an asymmetric arrangement of light-emitting elements or devices with a pixel.

An elevation of a portion of a yet further prior art display screen is shown in FIG. 3. In this arrangement, the minimum number of three complementary light-emitting elements are used to form the pixel. These comprise a red, green and blue element.

As with the arrangement in FIG. 2, louvers or shaders are provided in between each row to create an equal degree of obscuring to each of LEDs as a viewer shifts in the vertical plane. Similarly, as a viewer moves in the horizontal plane around the screen, the spacing between LEDs in a single row is kept constant to ensure LEDs within the row provide an equal degree of obscuring to the adjacent LED and prevent a particular colour-shift in respect of that row.

However, as shown in FIG. 3, the spacing between the red and green LEDs on the upper row is different than the equal spacing used between the blue LEDs on the lower row. If a viewer moves around a horizontal plane closer towards the edge of the screen, the intensity of the red and green LEDs drops equally with each other. However, the intensity of the blue LED drops less than the red and greens and creates a blue-shift in the colour of the overall image as seen by the viewer. At present many producers simply put up with such an effect if they utilize an asymmetric arrangement of light-emitting elements within the pixel as shown in FIG. 3.

Similarly problems may occur in other pixel arrangements such as arrangements of five light-emitting elements per pixel or if the distribution of colours is unequal on different rows.

### OBJECT OF THE INVENTION

It is an object of the present invention to provide a method and apparatus for reducing a colour-shift in a display screen when viewed from an off-centre position to reduce or minimize the effects described, particularly in display screens using an asymmetric arrangement of light-emitting elements in the display screen. It is at least an object of the invention to provide the public with a useful choice.

### SUMMARY OF THE INVENTION

Accordingly, in a first aspect, the invention may broadly be said to consist in a display screen having a plurality of light-emitting elements arranged in pixels in an arrangement having an axis of asymmetry wherein obscuring is are provided on or adjacent at least one light-emitting element within said display to substantially equate with the additional obscuring effect of adjacent light-emitting elements in an alternative portion of said display.

Preferably said display screen includes light-emitting elements that at least partially protrude from a front surface of said display screen.

Preferably said display screen includes rows of light-emitting elements at a first spacing and at least one further row of light-emitting elements at an alternative spacing and of an alternative colour arrangement.

Preferably said display screen provides louvers or shaders between rows of light-emitting elements on said display screen.

Preferably said obscuring means comprises at least one protrusion adjacent said at least one light-emitting element.

Preferably said at least one protrusion comprises a single protrusion of reduced dimension than the protrusion of a light-emitting element.

Alternatively or additionally said obscuring means includes at least one portion extending from an adjacent louver and positioned at least partially between adjacent light-emitting element in a row adjacent said louver.

Alternatively or additionally said obscuring means includes a coating or covering portion on a side off said light-emitting element.

Alternatively or additionally said obscuring means comprises a coating or physical barrier within an outer lens of a light-emitting element.

Accordingly, in a second aspect, the invention may broadly be said to consist in a method of reducing colour-shift in a display screen when viewed off-centre comprising the steps of:

providing an obscuring means in or adjacent a selection of a plurality of light-emitting elements to at least partially equate to the obscuring effect of adjacent light emitting elements amongst a remainder of said plurality of light-emitting elements.

Accordingly, in a third aspect, the invention may broadly be said to consist in a method of manufacturing a display screen comprising:

placing a plurality of light-emitting elements in an array and protruding from a front face of said display screen; and

providing obscuring means on or adjacent light-emitting elements within a row of said array to at least partially equate to an obscuring effect of a further row of light-emitting elements of reduced spacing and differing colour distribution within said array.

### BRIEF DESCRIPTION OF THE DRAWINGS

Preferred embodiments of the invention will now be described with reference to the following drawings in which:

FIG. 1a is a front elevation of a portion of a prior art display screen;

FIG. 1b is a cross-sectional elevation through the prior art screen of FIG. 1a;

FIG. 2 is a front elevational view of a portion of a further prior art display screen;

FIG. 3 is a front elevational view of a portion of a yet further prior art display screen;

FIG. 4a is a front elevational view of a portion of a display screen in accordance with an embodiment of the invention;

FIG. 4b is a cross-sectional side elevation through the portion of the apparatus of FIG. 4a;

FIG. 5a is an elevational view of a portion of a further embodiment of the invention;

FIG. 5b is an elevational view of a portion of a yet further embodiment of a display screen in accordance with the invention;

FIG. 6 is an elevational view of a light-emitting element in accordance with a further embodiment of the invention; and

FIG. 7 is an elevational view of a light-emitting element in accordance with a yet further embodiment of the invention.

### DETAILED DESCRIPTION OF PREFERRED EMBODIMENTS

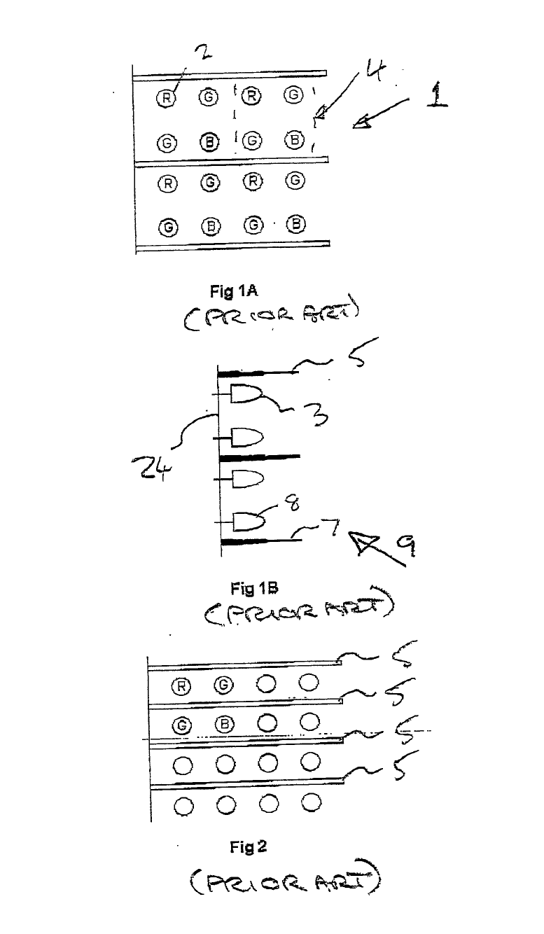

Referring initially to the prior art as described previously, a typical existing display screen 1 is shown in FIG. 1A in a front elevation. A plurality of light-emitting elements 2 such as the protruding LEDs 3 are provided extending from a front face 4 of the display screen.

Typically, louvers 5 may be provided to extend some shading against sun load and improve contrast in the appearance of the LEDs.

As shown in FIG. 1A, the LEDs 3 may be arranged into a pixel 4 comprising a group of, for example, four LEDs in a red-green-green-blue arrangement.

It will be appreciated that when an observer is viewing a screen from an angle other than directly in front of the LEDs, the louvers 5 may partially obscure adjacent LEDs. For example, as shown in FIG. 1B, a louver 7 may partially obscure an adjacent LED 8 when viewed in the direction of arrow 9.

In the arrangement as shown with red and green on an upper row and green and blue on a lower row, it will be appreciated that there is a greater degree of obscuring of the blue component of the pixel than of the red. This may cause a colour shift in viewing the screen.

Hence the arrangement shown in FIG. 2 arranges louvers 5 intermediate of every row of light-emitting elements such that every LED will receive the same obscuring effect when a user views at an angle on the vertical plane.

A greater difficulty is presented in the case of the asymmetric arrangement shown in FIG. 3. In this instance, there will still be same degree of obscuring effect in the vertical plane courtesy of the louvers 5. However, as each pixel only comprises three LEDs arranged on different rows, the unequal spacing between the red and green as compared to the adjacent blues on the line below will cause an uneven obscuring effect from one LED on its adjacent LED when viewed off-centre in the horizontal plane.

Typically, when a user moves to view the screen more towards the direction of the arrow 10, there is an obscuring effect of the red LED 11 on its adjacent green LED 12. As this obscuring effect is identical right along the row of LEDs, there is no appreciable colour shift to the user.

However, as the blue LED 14 obscures the more distal LED 15 much or less due to the greater spacing, the overall effect on the screen is a blue shift in the colour of the screen.

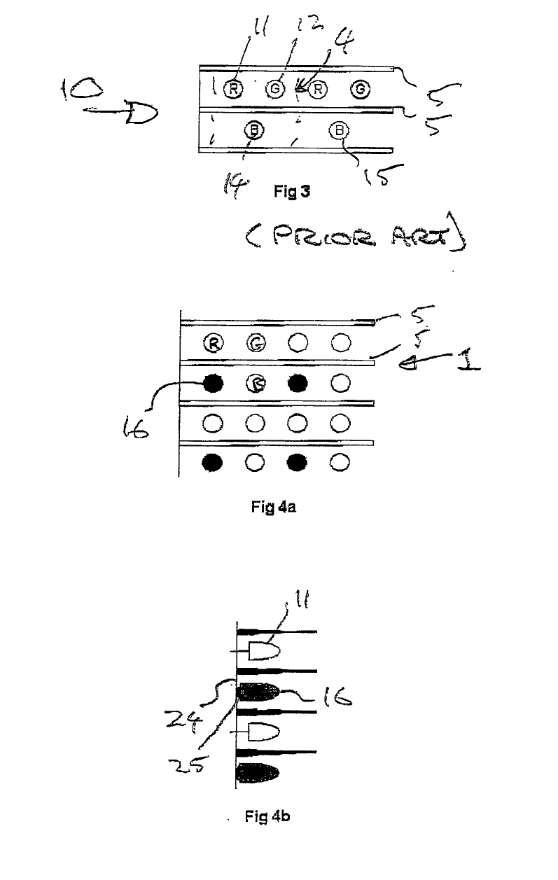

A preferred embodiment of the invention is shown in FIG. 4A. In this embodiment, the screen 1 still provides equate distant louvers 5 between each row to substantially equate the obscuring effects from the louvers themselves. Additionally, the red-green and blue light-emitting elements forming a single pixel may be arranged such that there is an unequal distance between the red and green LEDs as compared with adjacent blue LEDs on the line below.

Regardless, an additional obscuring means 16 may be provided intermediate of the blue LEDs to provide the same degree of obscuring effect on an adjacent blue LED as would have occurred had there been LEDs at equal spacing along that row identical to the row above.

As shown in FIG. 4B, a red LED 11 may be provided on the upper row and, beneath, the obscuring means 16 which, in this embodiment, comes in the form of a physical protrusion somewhat similar to an LED itself.

As it is important to contrast between the light-emitting elements and any background material on such screens, the protrusion 16 in the preferred embodiment shown in FIGS. 4A and 4B may be a black protrusion from the front face 24. This protrusion may be formed integrally with the material of the front face 24 or be an additional item suitably attached by any suitable connection mechanism 25 such as glue, other adhesive or other mechanical connection mechanisms.

In a typical example, the protrusion 16 would be of slightly small at dimension and projection than the light-emitting elements. It will be appreciated that when a user is viewing the screen more towards the side of the screen, any obscuring effect from, for example, the red LED 11 on the adjacent green LED 12 is partially negated by the transparency of the lens covers on these light-emitting elements. In contrast a physical protrusion 16 provided in a black solid colour to maximize contrast may need to be of smaller dimension to substantially equate to the obscuring effect of the red LED 11 on the adjacent LED 12.

The obscuring means 16 can be provided a variety of alternative forms and positions. Its intention is to try to ensure that there is an equal obscuring effect from adjacent LEDs. In the example shown in FIGS. 4A and 4B, the obscuring means 16 is provided only in the row of blue LEDs to bring this row to a point where it substantially equates to the row above. Of course, just as the louvers have been provided between every row to overcome the problem shown in FIG. 1A, obscuring means could be provided between LED such at there is substantially no obscuring effect from adjacent LEDs but only from the obscuring means themselves. This may again lead to a standard of obscuring effect as a viewer moves off-centre when viewing the screen on the horizontal plane.

A variety of alternative obscuring means are shown through the remaining figures.

Referring firstly to FIG. 5A, the obscuring means in this example may comprise one or more protrusions 17 extending from an adjacent louver 5. By minimizing the viewable portion of each LED through a gap 18, some control over the obscuring of the LEDs is provided. As shown in FIG. 5A, a pair of such extending portion 17 may be provided with one downwardly dependent from an upper louver 5 and another upwardly dependent from a louver beneath.

Referring to FIG. 5B, such portions dependent from adjacent louvers may be used in conjunction with additional obscuring means such as a projection 19 intermediate of dependent portions 26 and 21 projecting from adjacent louvers 5.

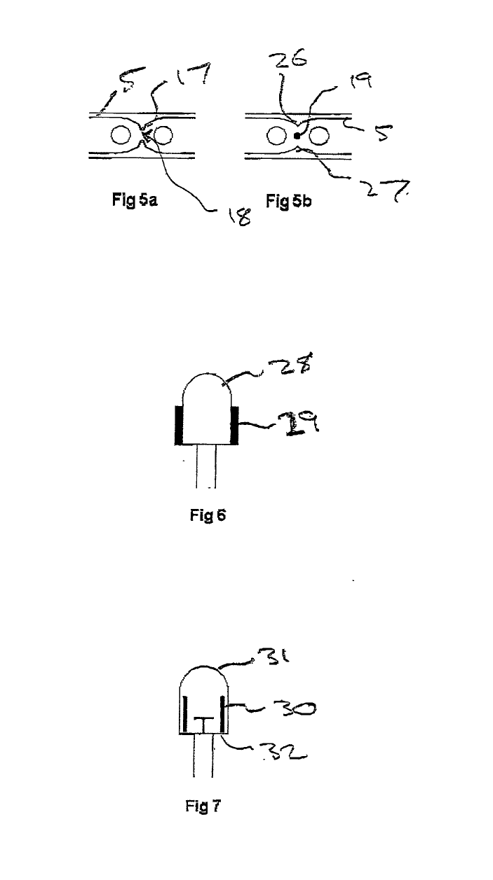

Referring to FIG. 6, it will also be appreciated that it is possible to not only provide obscuring means adjacent the LEDs in a physical form but also to provide obscuring means on an LED 28 by means of a coating 29 or similar. This coating may be applied adjacent the side portions of the LED to narrow the field of the emission of light from the LED and hence reduce its light once a viewer moves further around in the horizontal plane.

Referring to FIG. 7, the obscuring means 30 could be provided internally within the lens 31 of the LED and again may be provided in physical form by means of a projection from a base of the LED 32 or by a coating or deposition on the inside of the lens.

It will be appreciated that the invention provides a method of equating obscuring effects caused by adjacent LEDs by bringing those LEDs which may be less obscure down to the level of those most obscured. Although this way reduce the overall light received by a viewer when viewing the screen of centre, it may minimize colour shift such that the picture is at least apparent in the form intended.

Thus the invention provides preferred embodiments which overcome the problems in existing display screens.

Although this invention has been described with reference to preferred embodiments, it will be appreciated that the scope of the invention is as defined in the appended claims and should not be limited to those particular embodiments disclosed. Specific integers referred to throughout the description are deemed to incorporate known equivalents where appropriate.

1. A display screen having a plurality of light-emitting elements arrange in pixels in an arrangement having an axis of asymmetry wherein obscuring means are provided on or adjacent at least one light-emitting element within said display to substantially equate with the additional obscuring effect of adjacent light-emitting elements in an alternative portion of said display.

2. A display screen as claimed as claimed in claim 1 wherein said display screen includes light-emitting elements that at least partially protrude from a front surface of said display screen.

3. A display screen as claimed as claimed in claim 2 wherein said display screen includes rows of light-emitting elements at a first spacing and at least one is further row of light-emitting elements at an alternative spacing and of an alternative colour arrangement.

4. A display screen as claimed as claimed in claim 1 wherein said display screen provides louvers or shaders between rows of light-emitting elements on said display screen.

5. A display screen as claimed as claimed in claim 2 wherein said obscuring means comprises at least one protrusion adjacent said at least one light-emitting element.

6. A display screen as claimed as claimed in claim 5 wherein said at least one protrusion comprises a single protrusion of reduced dimension than the protrusion of a light-emitting element.

7. A display screen as claimed as claimed in claim 4 wherein said obscuring means includes at least one portion extending from an adjacent louver and positioned at least partially between adjacent light-emitting element in a row adjacent said louver.

8. A display screen as claimed as claimed in claim 1 wherein said obscuring means includes a coating or covering portion on a side off said light-emitting element.

9. A display screen as claimed as claimed in claim 1 wherein said obscuring means comprises a coating or physical barrier within an outer lens of a light-emitting element.

10. A method of reducing colour-shift in a display screen when viewed off-centre comprising the steps of:
providing an obscuring means in or adjacent a selection of a plurality of light-emitting elements to at least partially equate to the obscuring effect of adjacent light emitting elements amongst a remainder of said plurality of light-emitting elements.

11. A method of manufacturing a display screen comprising:
placing a plurality of light-emitting elements in an array and protruding from a front face of said display screen; and
providing obscuring means on or adjacent light-emitting elements within a row of said array to at least partially equate to an obscuring effect of a further row of light-emitting elements of reduced spacing and differing colour distribution within said array.
